(19) United States
(12) Patent Application Publication
(10) Pub. No.: US 2026/0372057 A1
(43) Pub. Date: Nov. 19, 2026

(54) SEMICONDUCTOR INTEGRATED CIRCUIT WITH INTER-DIE CONNECTIONS FORMED BY REDISTRIBUTION LAYER

(71) Applicant: EINSNEXT PTE. LTD., Singapore (SG)

(72) Inventors: TSUNG YU CHEN, Hsinchu County (TW); Yantao Jia, Stow, MA (US); Ming-Te Hung, Hsinchu County (TW)

(21) Appl. No.: 19/208,621

(22) Filed: May 15, 2025

(51) Int. Cl. H10W 20/43; H10B 80/00; H10D 80/30; H10W 20/42; H10W 90/00; H10W 72/00; H10W 72/90; H10W 80/00

(52) U.S. Cl. CPC H10W 20/43; H10B 80/00; H10D 80/30; H10W 20/42; H10W 90/00; H10W 72/0198; H10W 72/9445; H10W 80/312; H10W 80/327; H10W 90/753; H10W 90/792

(57) ABSTRACT

There is provided a semiconductor integrated circuit including a logic wafer and a memory wafer. The logic wafer includes multiple logic dies. The memory wafer includes multiple memory dies with inter-die connections between adjacent memory dies and located at backsides of the memory dies. The logic wafer is bonded onto the memory wafer to cause the multiple logic dies to communicate to adjacent logic dies via the inter-die connections and through silicon vias on the memory wafer.

### FIELD OF THE DISCLOSURE

This disclosure generally relates to a semiconductor integrated circuit and, more particularly, to a semiconductor integrated circuit with inter-die connections formed by an additional redistribution layer (RDL).

### BACKGROUND OF THE DISCLOSURE

The artificial intelligence requires extremely large data sets in training algorithms, but the underlying computer architecture is not sufficient enough for the artificial intelligence training.

The present disclosure provides a semiconductor integrated circuit that fulfills the requirement of dealing with large data sets in artificial intelligence training.

The information disclosed in this BACKGROUND is merely intended to increase understanding of the general background of the invention and should not be taken as an admission or in any way implied that the relevant information constitutes prior art that is already known to a person of ordinary skill in the art.

### SUMMARY

Accordingly, the present disclosure provides a semiconductor integrated circuit in which inter-die communication between logic dies of a logic wafer is implemented through inter-die connections between memory dies on a memory wafer, wherein the inter-die connections are formed on backsides of the memory dies.

The present disclosure further provides a semiconductor integrated circuit in which inter-die communication between logic dies of a logic wafer is implemented by an additional redistribution layer (RDL).

The present disclosure provides a semiconductor integrated circuit including two logic dies and two memory dies. The two logic dies are adjacent to each other. The two memory dies are adjacent to each other and provided with at least one inter-die connection therebetween, and the at least one inter-die connection is located at backsides of the two memory dies. Each of the two logic dies is bonded to each of the two memory dies through hybrid bond to cause one of the two logic dies to communicate with the other one of the two logic dies through the hybrid bond and the at least one inter-die connection.

The present disclosure further provides a semiconductor integrated circuit including a logic wafer and a memory wafer. The logic wafer includes multiple logic dies. The memory wafer includes multiple memory dies with inter-die connections between the multiple memory dies, and the inter-die connections are located at a backside of the memory wafer. The memory wafer is bonded onto the logic wafer to cause adjacent logic dies of the logic wafer to be electrically coupled to each other via the inter-die connections on the memory wafer.

The present disclosure further provides a semiconductor integrated circuit including two logic dies and a redistribution layer. The two logic dies are adjacent to each other. The redistribution layer includes at least one conductive wire crossing from one of the two logic dies to the other one of the two logic dies to form at least one inter-die connection between the two logic dies.

In the present disclosure, an inter-die communication between two logic dies is implemented by hybrid bond extending from logic dies to memory dies as well as a transverse inter-die connection, formed by RDL, at backsides of corresponding two memory dies.

### BRIEF DESCRIPTION OF DRAWINGS

Other objects, advantages, and novel features of the present disclosure will become more apparent from the following detailed description when taken in conjunction with the accompanying drawings.

FIG. 1 is a plane view of two logic dies according to one embodiment of the present disclosure.

FIG. 2 is a cross sectional view of the logic dies along line 2-2’ in FIG. 1 according to one embodiment of the present disclosure.

FIG. 3 is a plane view of two memory dies according to one embodiment of the present disclosure.

FIGS. 3A-3C are schematic diagrams of steps for manufacturing the memory dies in FIG. 3.

FIG. 4 is a cross sectional view of a semiconductor integrated circuit according to one embodiment of the present disclosure.

FIG. 5 is a flow chat of a method for manufacturing a semiconductor integrated circuit according to one embodiment of the present disclosure.

FIG. 6 is a schematic diagram of a logic wafer according to one embodiment of the present disclosure.

FIG. 7 is a schematic diagram of a memory wafer according to one embodiment of the present disclosure.

FIG. 8A is a cross sectional view of two logic dies according to another embodiment of the present disclosure.

FIG. 8B is a cross sectional view of two memory dies stacking on two logic dies according to another embodiment of the present disclosure.

### DETAILED DESCRIPTION OF THE DISCLOSURE

It should be noted that, wherever possible, the same reference numbers will be used throughout the drawings to refer to the same or like parts.

One objective of the present disclosure is to provide a semiconductor integrated circuit including a memory wafer stacked on a logic wafer to form so-called wafer-on-wafer (WoW) structure. The memory wafer includes multiple memory dies with inter-die connections, which are used to provide inter-die communication between logic dies of the logic wafer, located at a backside (a side not facing the logic die) of the memory wafer. That is, the inter-die communication of the logic wafer is implemented by the inter-die connections of a different wafer stacked thereon and hybrid-bonded thereto.

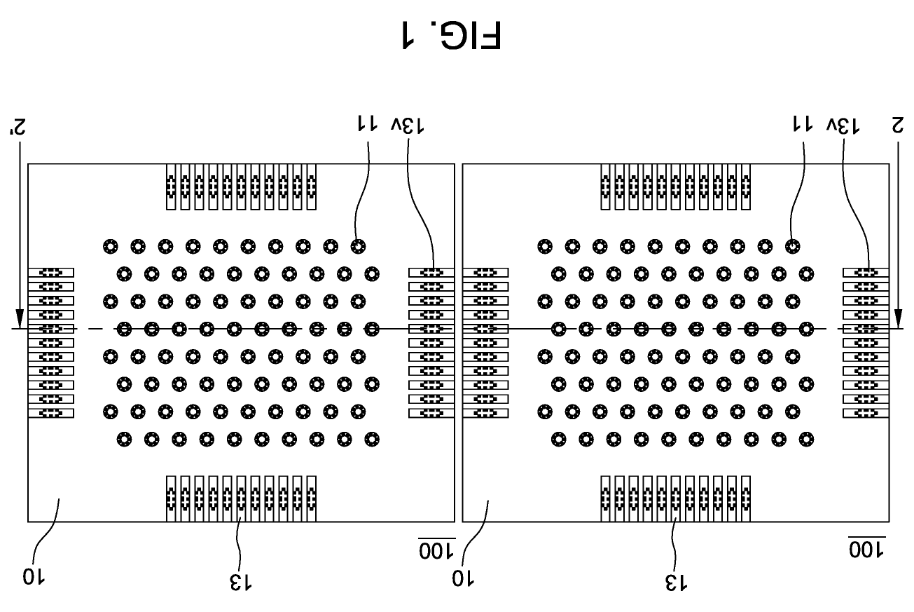

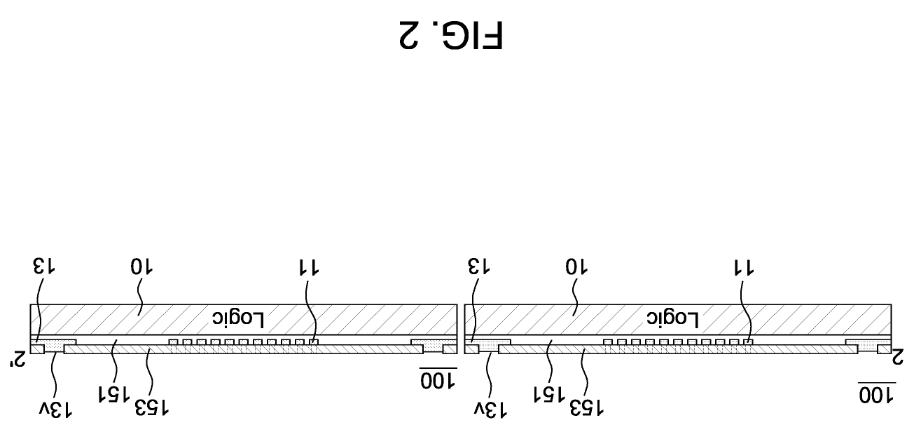

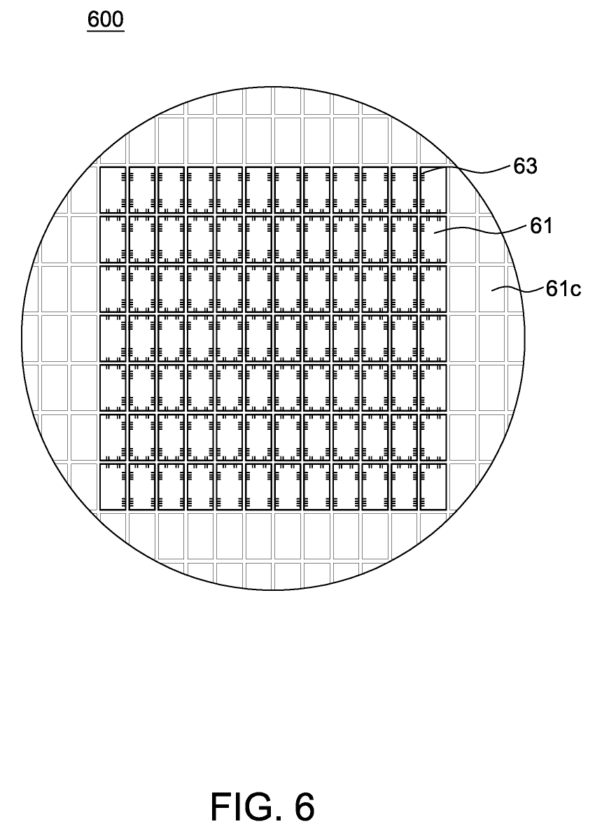

Please refer to FIGS. 1-2, FIG. 1 is a plane view of two logic dies 100 according to one embodiment of the present disclosure; and FIG. 2 is a cross sectional view of the logic dies 100 along line 2-2’ in FIG. 1 according to one embodiment of the present disclosure. It should be mentioned that although FIGS. 1-2 use two adjacent logic dies 100 as an example for illustration, it is only intended to illustrate but not to limit the present disclosure. A logic wafer may include multiple logic dies, e.g., as shown in FIG. 6. In another aspect, the logic wafer of the present disclosure is a system-on-chip (SoC) wafer which includes multiple SoC dies.

Each logic die 100 includes a circuit layer (or called substrate) 10, a first non-conductive layer 151, multiple bond pads 11, a first redistribution layer (RDL) 13 and a second non-conductive layer 153. The material of the first non-conductive layer 151 and the second non-conductive layer 153 are not particularly limited as long as they can electrically isolate components therein. The method of forming a non-conductive layer on a substrate is known to the art and not a main objective of the present disclosure, and thus details thereof are not described herein.

The circuit layer 10 includes microelectronic devices (not shown) therein such as transistors, diodes and various circuits for performing predetermined functions thereof, and the microelectronic devices are formed by photolithographic processes, which are known to the art and thus details thereof are not described herein.

The multiple bond pads 11 are for hybrid bonding to electrically couple the circuit layer 10 to external devices or components, e.g., to a corresponding memory die 300 mentioned below.

The first redistribution layer 13 includes at least one conductive wire (multiple wires being shown at four edges of each logic die 100). In one aspect, the at least one conductive wire extends perpendicularly to edges of the logic die 100. The first redistribution layer 13 is electrically connected to logic circuits inside the circuit layer 10, e.g., connecting to a transmitting circuit and a receiving circuit of a logic die 100 in order to send out and receive communication signals.

The second non-conductive layer 153 covers on the first redistribution layer 13 and the first non-conductive layer 151, and is formed with at least one bond 13v corresponding to each conductive wire to expose a part of each conductive wire for electrical connection with a memory die.

In the present disclosure, numbers of the conductive wires and the bonds 13v are determined according to communication requirement, e.g., bandwidth and connectivity, between the logic dies 100.

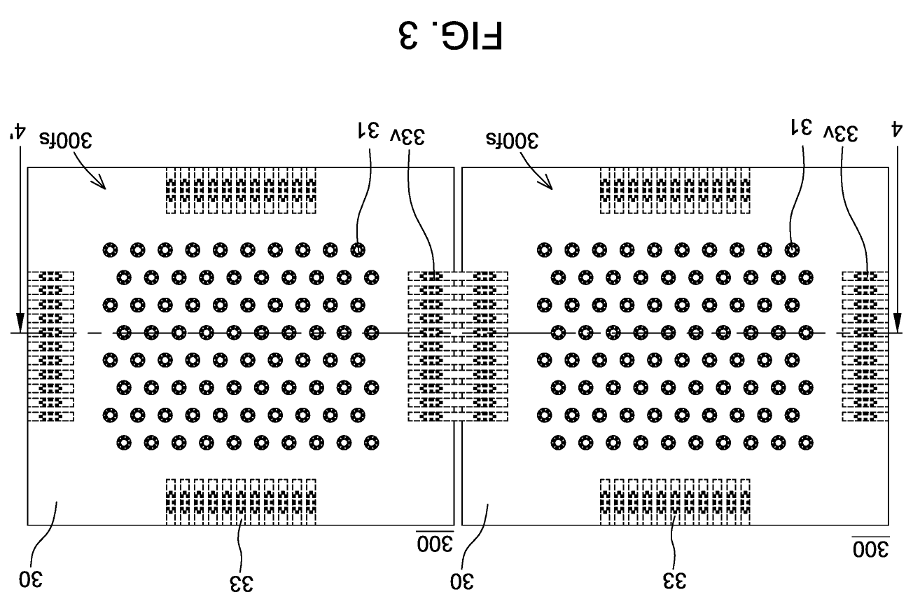

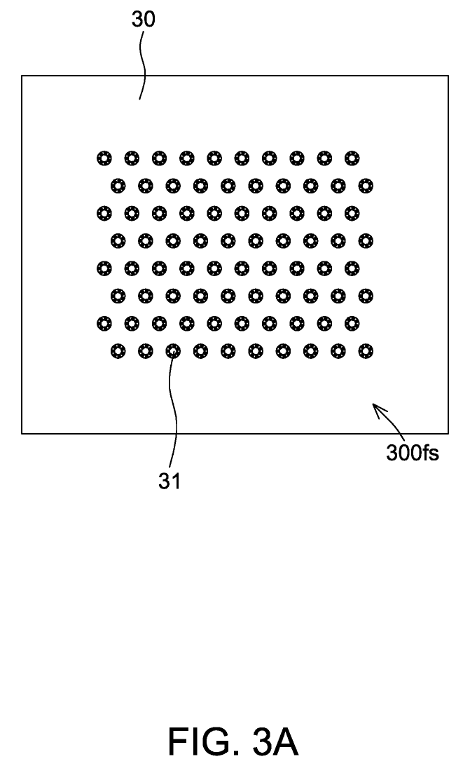

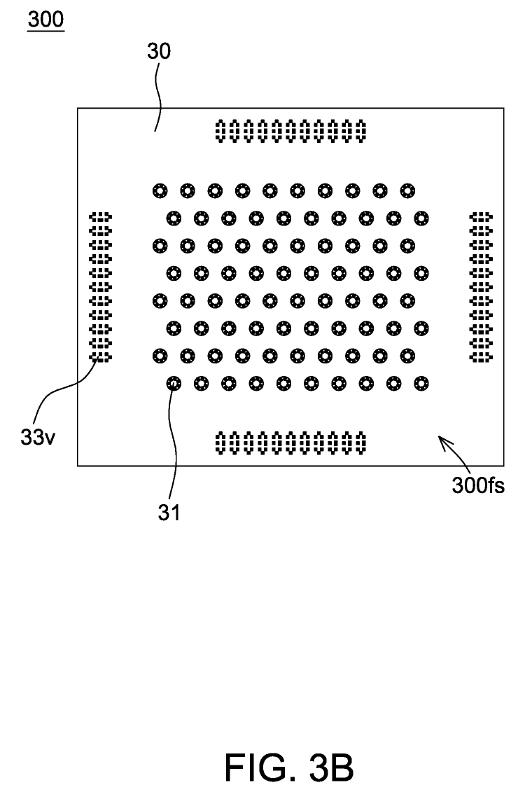

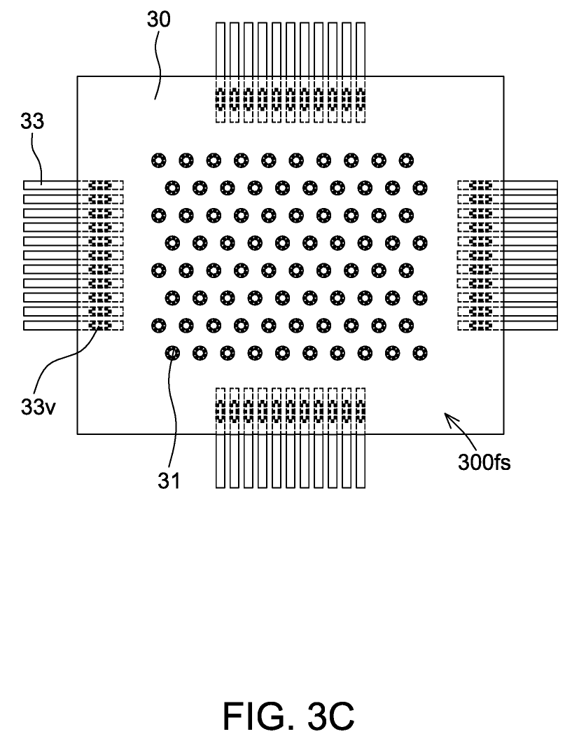

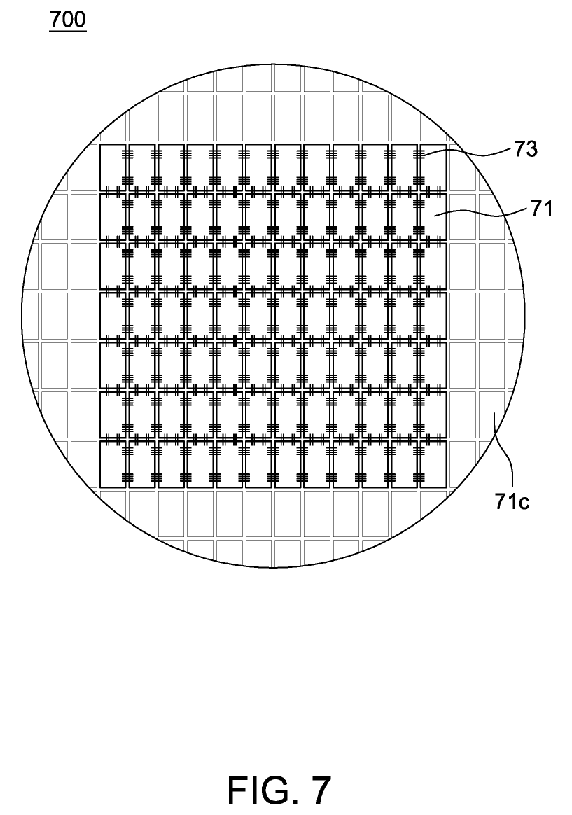

Please refer to FIGS. 3 and 4, FIG. 3 is a plane view of two memory dies 300 according to one embodiment of the present disclosure; and FIG. 4 is a cross sectional view of two logic dies 100, along line 2-2’ in FIG. 1, and two memory dies 300, along line 4-4’ in FIG. 3, according to one embodiment of the present disclosure. It should be mentioned that although FIGS. 3 and 4 use two adjacent memory dies 300 as an example for illustration, it is only intended to illustrate but not to limit the present disclosure. A memory wafer may include multiple memory dies, e.g., as shown in FIG. 7. It is appreciated that a top surface (e.g., front side 300fs) in FIG. 3 is faced downward in FIG. 4 for illustration purposes. Each memory die 300 has a backside 300bs opposite to the front side 300fs.

Each memory die 300 includes a circuit layer (or called substrate) 30, a first non-conductive layer 351, multiple bond pads 31, a second redistribution layer 33 and a second non-conductive layer 353. Similarly, the material of the first non-conductive layer 351 and the second non-conductive layer 353 are not particularly limited as long as they can electrically isolate components therein.

The circuit layer 30 includes circuits such as transistors, diodes and various circuits formed by photolithographic processes having predetermined functions.

The multiple bond pads 31 are for hybrid bonding to electrically couple the circuit layer 30 to external devices or components, e.g., to a corresponding logic die 100.

The second redistribution layer 33 includes at least one conductive wire (multiple wires being shown at four edges of each memory die 300 and at the backside 300bs, shown by dashed line in FIG. 3). In one aspect, the at least one conductive wire extends perpendicularly out of edges of the memory die 300 and connects to adjacent memory dies. That is, two adjacent memory dies 300 are connected by at least one inter-die connection (i.e. conductive wire) 33c therebetween, and each of the two adjacent memory dies 300 includes a second redistribution layer 33 to form the at least one inter-die connection 33c. In one aspect, the inter-die connections 33c are arranged perpendicular to edges of the multiple memory dies 300. The inter-die connections (i.e. RDL) 33 are used to connect adjacent memory dies, but are not connected to any circuit inside the memory dies.

In this embodiment, each of the memory dies 300 further includes at least one via (through silicon via, TSV) 33v penetrating from the front side 300fs to the backside 300bs and connected to the second redistribution layer 33. In this way, the first redistribution layer 13 of the logic dies 100 is electrically coupled to the second redistribution layer 33 of the memory dies 300 via the at least one via 33v.

It should be mentioned that although FIG. 3 shows that only the conductive wires between adjacent memory dies 300 form inter-die connections, and the conductive wires at other edges (not between dies) of the memory dies 300 are not extended out of the edges, it is only intended to illustrate but not to limit the present disclosure. In another aspect, edges between two memory dies 300 may not arranged with any conductive wire if no inter-die communication is required between the two memory dies 300.

The second non-conductive layer 353 covers on the multiple bond pads 31 and the first non-conductive layer 351, and is formed with at least one via 33v corresponding to each conductive wire and coupled to the second redistribution layer for electrical connection of one memory die 300 to one logic die 100.

Please refer to FIG. 4, in the present disclosure, each of the logic dies 100 is bonded to one of the memory dies 300 through bonds on bond pads 11 and 31 and longitudinal vias 33v in the memory dies 300 to cause one of the logic dies 100 to communicate with another one (adjacent one, but not limited to) of the logic dies 100 through the longitudinal vias 33v and the at least one inter-die connection 33c.

In the integrated circuit of the present disclosure, one of the logic dies 100 communicates with another one of the logic dies 100 not through the multiple bond pads 11 or the multiple bond pads 31; one of the logic dies 100 communicates with another one of the logic dies 100 through the first redistribution layer 13 and the second redistribution layer 33. In bonding the logic die 100 to the memory die 300, the bonds 13v are aligned with the vias 33v to cause the first redistribution layer 13 to be electrically coupled with the second redistribution layer 33 to form a communication channel between the logic die 100 and the memory die 300.

In the present disclosure, the second redistribution layer 33 of the memory dies 300 is not connected to any circuit inside the memory dies 300. That is, the inter-die connections 33c are not used to transmit signals from memory cells in one memory die 300 to memory cells in another memory die 300.

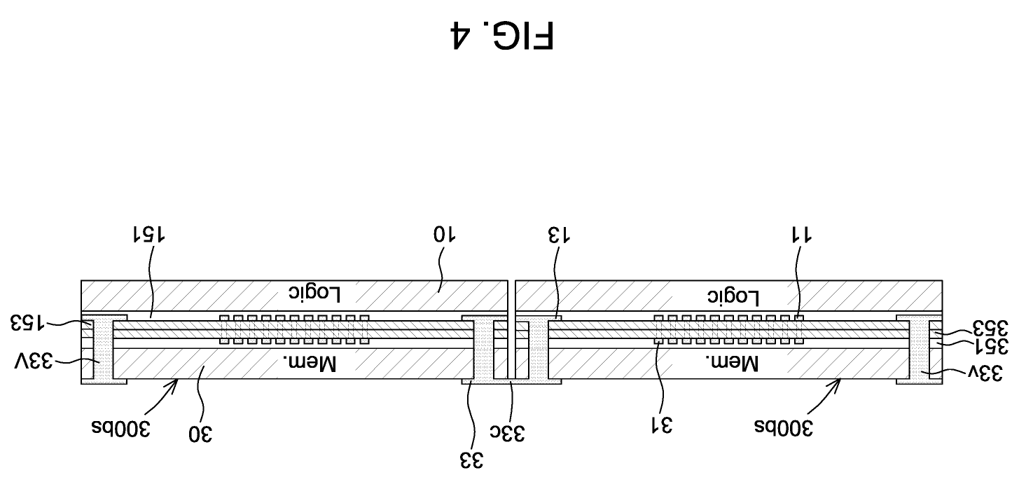

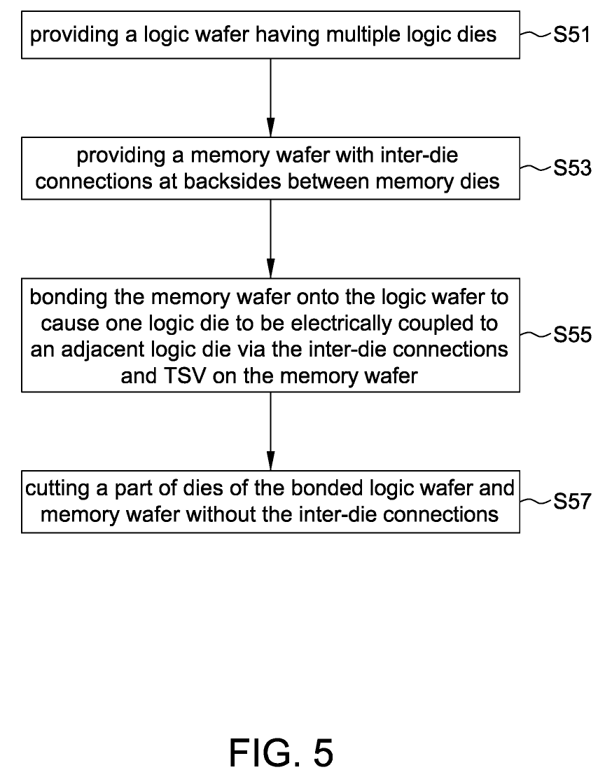

Please refer to FIG. 5, it is a flow chat of a method for manufacturing a semiconductor integrated circuit according to one embodiment of the present disclosure. The method includes the steps of: providing a logic wafer having multiple logic dies (Step S51); providing a memory wafer having multiple memory dies and inter-die connections between the multiple memory dies (Step S53); bonding the memory wafer onto the logic wafer to cause one logic die on the logic wafer to be electrically coupled to an adjacent logic die via the inter-die connections on the memory wafer (Step S55); and cutting a part of dies of the bonded logic wafer and memory wafer without the inter-die connections (Step S57).

Step S51: Please refer to FIG. 6 together, each of the logic dies 61 (identical to 100 in FIGS. 1-2) includes transmitting and receiving circuits therein for communicating with an adjacent logic die 61. Other microelectronic devices included in each logic die 61 are determined according to an application of the semiconductor integrated circuit. The logic wafer 600 includes a first redistribution layer 63 (identical to 13 in FIGS. 1-2) formed on the multiple logic dies 61, and the first redistribution layer 63 includes bonds 13v, which are formed by photolithography processes. The method of forming bonds penetrating through non-conductive layer (e.g., 153) is known to the art and thus details thereof are not described herein.

Step S53: Please refer to FIG. 7 together, each of the memory dies 71 (identical to 300 in FIGS. 3-4) includes circuits therein. The structure of a memory die is not particularly limited herein. The memory wafer 700 includes inter-die connections 73 (identical to 33c in FIGS. 3-4) between the multiple memory dies 71 formed by RDLs. As mentioned above, the inter-die connections 73 are not connected to the circuits inside the memory dies 71. The memory wafer 700 includes a second redistribution layer 73 (identical to 33 in FIGS. 3-4) formed on the multiple memory dies 71, and the second redistribution layer 73 includes through silicon vias 33v.

Step S55: After bonding the logic wafer 600 with the memory wafer 700, each logic die 61 is aligned with one memory die 71 such that adjacent logic dies 61 of the logic wafer 600 are electrically coupled to each other via the inter-die connections 73 on the memory wafer 700. The bonds 13v are aligned with the through silicon vias 33v (referred to FIG. 4) to be connected to the inter-die connections 73 (i.e. 33c in FIG. 4) such that the first redistribution layer 63 is electrically coupled with, formed by hybrid bonding, the second redistribution layer 73 through the through silicon vias vias 51.

Since the inter-die connections 73 are used as communication channels between two or more logic dies 61, the inter-die connections 73 are preferably electrically coupled to at least the transmitting circuits and receiving circuits of the logic dies 61 but not electrically coupled to any circuit inside the memory dies 71.

Step S57: Finally, a cutting machine is used to cut off a part of dies of the bonded logic wafer and memory wafer without the inter-die connections, e.g., logic dies 61c shown by thinner lines in FIG. 6 and memory dies 71c shown by thinner lines in FIG. 7. After the dies 61c and 71c are cut off, the remained inter-die connected dies form the semiconductor integrated circuit of the present disclosure, which may then be packaged and arranged on a circuit boarded/film according to applications thereof.

It is appreciated that the bonded logic wafer and memory wafer further includes input/out connections (or fanouts) to interact with devices external to the semiconductor integrated device of the present disclosure.

Please refer to FIGS. 3A-3C, in one aspect, a memory die provided by a vendor (e.g., FIG. 3A) is further processed to form the memory die 300 of the present disclosure. For example, a third part further processes a memory die with bond pads 31 in FIG. 3A to form multiple through silicon vias 33v penetrating from a front side 300fs to a backside 300bs, referring to FIG. 3B. Next, conductive wires (as redistribution layer 33 in FIG. 3) perpendicular to edges of a memory die are formed at the backside 300bs as the inter-die connections, referring to FIG. 3C. In another aspect, it is possible that the vendor directly provides a memory wafer 300 including multiple memory dies 300 as shown in FIG. 3C.

In the present disclosure, the logic wafer 600 and the memory wafer 700 may be manufactured separately and then bonded together using wafer-on-wafer (WoW) manufacturing process.

It should be mentioned that a number of and positions of dies capable of performing inter-die communication as well as a number of and positions of conductive wires shown in FIGS. 6-7 of the present disclosure are only intended to illustrate but not to limit the present disclosure. That is, a shape of the bonded logic wafer and memory wafer is not limited to a rectangular shape as shown in FIGS. 6-7.

It should be mentioned that a part of the wafers 600 and 700 may be used to manufacture dies without inter-die connections, and another part of the wafers 600 and 700 may be used to manufacture dies with inter-die connections as mentioned herein.

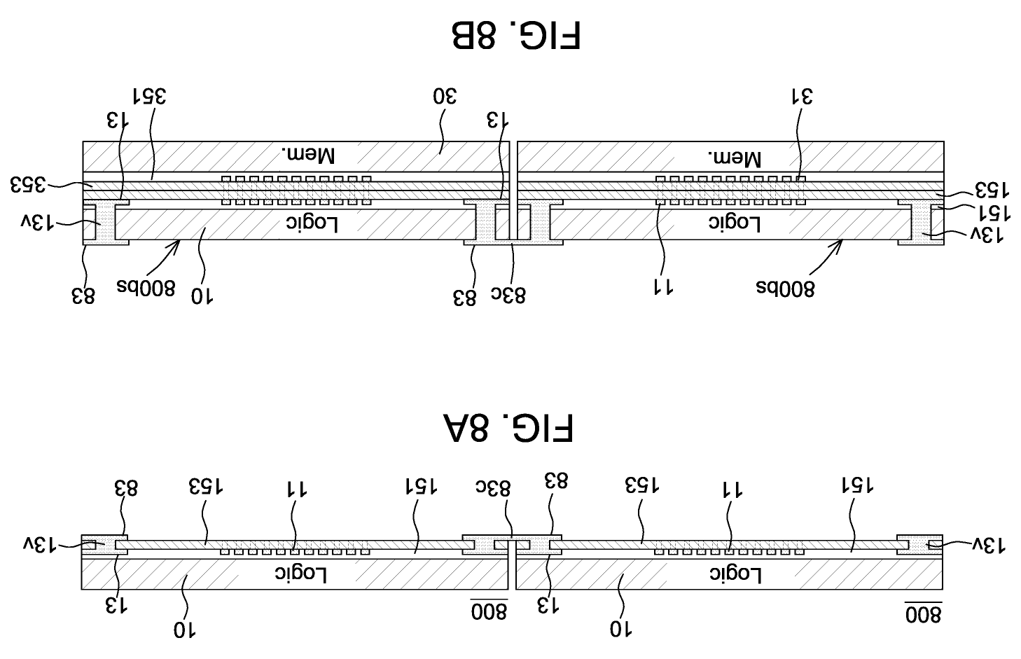

Please refer to FIG. 8A, it is a cross sectional view of two logic dies 800 according to another embodiment of the present disclosure. It should be mentioned that although FIG. 8A uses two adjacent logic dies 800 as an example for illustration, it is only intended to illustrate but not to limit the present disclosure. A logic wafer may include multiple logic dies, e.g., as shown in FIG. 6.

Each logic die 800 includes a circuit layer 10, a first non-conductive layer 151, multiple bond pads 11, a first redistribution layer 13, at least one bond 13v and a second non-conductive layer 153, similar to FIG. 2, and further includes a second redistribution layer 83. The difference between the embodiment of FIG. 8A and that of FIG. 2 is that the inter-die connection 83c is formed by the second redistribution layer 83. That is, the second redistribution layer 83 includes at least one conductive wire crossing from one of the two logic dies 800 to the other one of the two logic dies 800 to form at least one inter-die connection 83c between the two logic dies 800. Details of the first non-conductive layer 151, the multiple bond pads 11, the first redistribution layer 13, the bond 13v and the second non-conductive layer 153 are identical to those mentioned above, and thus are not repeated herein.

In this embodiment, the first redistribution layer 13 and the second redistribution layer 83 are formed by a die-first process or by a die-last process without particular limitations.

Similarly, since the inter-die connection 83c is used as a communication channel, the first redistribution layer 13 and the second redistribution layer 83 of the two logic dies 800 are electrically coupled to at least the transmitting and receiving circuits in the two logic dies 800.

It should be mentioned that although FIG. 8A shows that the inter-die connection is formed at a front side of the logic dies 800, it is only intended to illustrate but not to limit the present disclosure. In another aspect, the second redistribution layer 83 is formed at backsides 800bs, referring to FIG. 8B, of the logic dies 800 to form the inter-die connection 83c at the backsides 800bs of the logic dies 800.

In FIG. 8B, two memory dies are respectively stacking on the two logic dies, and multiple bond pads 31 are hybrid bonded to multiple bond pads 11 to electrically couple the circuit layer 30 to the circuit layer 10 as mentioned above. The memory dies are not required to form redistribution layer to be electrically coupled to the TSV 13V and the first redistribution layer 13 of the logic dies.

It should be mentioned that although FIG. 8B uses two adjacent logic dies 800 and two memory dies as an example for illustration, it is only intended to illustrate but not to limit the present disclosure. A logic wafer may include multiple logic dies, e.g., similar to FIG. 6 but with inter-die connections between logic dies; and a memory die may include multiple memory dies, e.g., similar to FIG. 7 but without inter-die connections between memory dies.

Unlike conventional wafer-scale interconnect solutions, which require die-to-die routing to be fabricated using additional mask layers during front-end-of-line (FEOL) or middle-of-line (MOL) processing within the same foundry. The present disclosure enables die-to-die connectivity using a post-fabrication Redistribution Layer (RDL) formed externally, after standard wafer fabrication is complete.

The present disclosure implements die-to-die interconnects via one or more Redistribution Layers (RDLs) applied on the surface of diced or reconstituted dies or wafers. The RDL serves to fan out the IOs from multiple dies and electrically bridge them over an interposer or reconstituted wafer without requiring modification to the original die layout or additional photolithography masks during FEOL processing.

This decouples the die-to-die interconnect architecture from the foundry process and allows for: foundry-agnostic fabrication, greater layout flexibility, lower NRE costs (no custom masks), and supporting for heterogeneous dies (from different nodes or vendors).

The method for establishing die-to-die interconnects of the present disclosure includes the steps of: fabricating a plurality of dies using a standard foundry process without custom inter-die routing layers; and forming a redistribution layer (RDL) across a reconstituted wafer or interposer substrate, wherein said RDL electrically connects terminals of adjacent dies to implement wafer-level or package-level inter-die communication, independent of front-end mask customization.

Conventional approaches require intra-wafer routing during wafer fabrication, thus lock the design to a single foundry flow and limit post-silicon reconfiguration. In contrast, the present disclosure enables die-to-die interconnection post-fabrication through additive RDL processing, which may be done at a separate facility or OSAT.

In the present disclosure, a longitudinal direction is referred to a stacking direction of wafers/dies, and a transverse direction is referred to a direction parallel to a top surface of the wafers/dies.

In the present disclosure, the substrate is preferably formed of a silicon material (e.g., pure silicon), but may be additionally or alternatively formed of any suitable known material without particular limitations.

In the present disclosure, numbers of the first redistribution layer and the second redistribution layer are not limited to only one layer. It is possible that the first redistribution layer and the second redistribution layer respectively include multiple stacked redistribution layers. In addition, the first redistribution layer and the second redistribution layer may be formed by a die-first process or by a die-last process without particular limitations.

As mentioned above, the artificial intelligence requires extremely large data sets in a training stage and the underlying computer architecture is not sufficient enough for the artificial intelligence training. Accordingly, the present disclosure further provides a semiconductor integrated circuit (e.g., FIGS. 4 and 8) and a method for manufacturing the semiconductor integrated circuit (e.g., FIG. 5) in which adjacent logic dies in a logic wafer communicate with each other through inter-die connections between memory dies in a memory wafer. In the present disclosure, adjacent memory dies do not communicate with each other through the inter-die connections. The inter-die connections are only for the communication between dies in another wafer. That is, communication signals of a first logic die go out of the first logic die to a first memory die stacked on the first logic die, then the communication signals go to a second memory die adjacent to the first memory die, and finally the communication signals go to a second logic die adjacent to the first logic die from the second memory die stacked on the second logic die.

Although the disclosure has been explained in relation to its preferred embodiment, it is not used to limit the disclosure. It is to be understood that many other possible modifications and variations can be made by those skilled in the art without departing from the spirit and scope of the disclosure as hereinafter claimed.

1. A semiconductor integrated circuit, comprising:
two logic dies, adjacent to each other; and
two memory dies, adjacent to each other and provided with at least one inter-die connection therebetween and the at least one inter-die connection being located at backsides of the two memory dies, wherein
each of the two logic dies is bonded to each of the two memory dies through hybrid bond to cause one of the two logic dies to communicate with the other one of the two logic dies through the hybrid bond and the at least one inter-die connection.

2. The semiconductor integrated circuit as claimed in claim 1, wherein
each of the two logic dies comprises multiple first bond pads,
each of the two memory dies comprises multiple second bond pads, and
the one of the two logic dies is configured to communicate with the other one of the two logic dies not through the multiple first bond pads or the multiple second bond pads.

3. The semiconductor integrated circuit as claimed in claim 1, wherein
each of the two logic dies comprises a first redistribution layer,
each of the two memory dies comprises a second redistribution layer configured as the at least one inter-die connection, and
the one of the two logic dies is configured to communicate with the other one of the two logic dies through the first redistribution layer and the second redistribution layer.

4. The semiconductor integrated circuit as claimed in claim 3, wherein the second redistribution layer of the two memory dies is not connected to any circuit in the two memory dies.

5. The semiconductor integrated circuit as claimed in claim 3, wherein the first redistribution layer of the two logic dies is connected to transmitting and receiving circuits in the two logic dies.

6. The semiconductor integrated circuit as claimed in claim 3, wherein
each of the two memory dies further comprises at least one via penetrating from a front side to the backside and connected to the second redistribution layer, and
the first redistribution layer is electrically coupled to the second redistribution layer via the at least one via.

7. The semiconductor integrated circuit as claimed in claim 3, wherein
the first redistribution layer comprises at least one conductive wire extending perpendicularly to an edge of each logic die, and
the second redistribution layer comprises at least one conductive wire extending perpendicularly out of an edge of each memory die.

8. A semiconductor integrated circuit, comprising:
a logic wafer, comprising multiple logic dies; and
a memory wafer, comprising multiple memory dies with inter-die connections between the multiple memory dies and the inter-die connections being located at a backside of the memory wafer, wherein
the memory wafer is bonded onto the logic wafer to cause adjacent logic dies of the logic wafer to be electrically coupled to each other via the inter-die connections on the memory wafer.

9. The semiconductor integrated circuit as claimed in claim 8, wherein the inter-die connections are arranged perpendicular to edges of the multiple memory dies.

10. The semiconductor integrated circuit as claimed in claim 8, wherein
each of the memory dies comprises circuits therein, and
the inter-die connections are not electrically coupled to the circuits in the memory dies.

11. The semiconductor integrated circuit as claimed in claim 8, wherein
each of the logic dies comprises transmitting and receiving circuits, and
the inter-die connections are electrically coupled to the transmitting and receiving circuits of the logic dies.

12. The semiconductor integrated circuit as claimed in claim 8, wherein
the logic wafer further comprises a first redistribution layer formed on the multiple logic dies,
the memory wafer further comprises a second redistribution layer formed on the multiple memory dies, and
each of the multiple memory dies further comprises at least one via penetrating from a front side of the memory wafer to the backside and connected to the second redistribution layer.

13. The semiconductor integrated circuit as claimed in claim 12, wherein the first redistribution layer is electrically coupled to the second redistribution layer via the at least one via.

14. The semiconductor integrated circuit as claimed in claim 8, wherein
each of the logic dies comprises multiple first bond pads,
each of the memory dies comprises multiple second bond pads, and
each of the logic dies is configured to communicate with an adjacent logic die thereof not through the multiple first bond pads or the multiple second bond pads.

15. A semiconductor integrated circuit, comprising:
two logic dies, adjacent to each other;
a redistribution layer, comprising at least one conductive wire crossing from one of the two logic dies to the other one of the two logic dies to form at least one inter-die connection between the two logic dies.

16. The semiconductor integrated circuit as claimed in claim 15, wherein the redistribution layer is formed by a die-first process or by a die-last process.

17. The semiconductor integrated circuit as claimed in claim 15, wherein the redistribution layer of the two logic dies is connected to transmitting and receiving circuits in the two logic dies.

18. The semiconductor integrated circuit as claimed in claim 15, wherein the at least one inter-die connection is arranged on front sides or backside of the two logic dies.
